(19) United States
(12) Patent Application Publication
(10) Pub. No.: US 2013/0224951 A1
(43) Pub. Date: Aug. 29, 2013

(54) TEMPLATE AND SUBSTRATE PROCESSING METHOD

(71) Applicant: TOKYO ELECTRON LIMITED, (US)

(72) Inventor: Haruo IWATSU, Koshi-shi (JP)

(73) Assignee: TOKYO ELECTRON LIMITED, Minato-ku (JP)

(21) Appl. No.: 13/861,712

(22) Filed: Apr. 12, 2013

Related U.S. Application Data
(63) Continuation of application No. PCT/JP2011/073206, filed on Oct. 7, 2011.

(30) Foreign Application Priority Data
Oct. 13, 2010 (JP) 2010-230738

(51) Int. Cl. B05C 5/00; H01L 21/308; H01L 21/768

(52) U.S. Cl. CPC B05C 5/00; H01L 21/76877; H01L 21/308
USPC 438/674; 239/548; 239/1; 438/745

(57) ABSTRACT

A template for feeding a processing solution to predetermined positions of a substrate has multiple opening portions formed in positions on a front surface corresponding to the predetermined positions, flow channels penetrating from the opening portions to a back surface in a thickness direction for flowing a processing solution, first hydrophilic regions set to be hydrophilic around the opening portions on the front surface, and second hydrophilic regions set to be hydrophilic on inner surfaces of flow channels. The first hydrophilic regions are formed in positions corresponding to hydrophilic patterns set to be hydrophilic around the predetermined positions on a substrate surface.

### CROSS-REFERENCE TO RELATED APPLICATIONS

The present application is a continuation of PCT International Application No. PCT/JP2011/073206, filed Oct. 7, 2011, which is based upon and claims the benefit of priority from Japanese Application No. 2010-230738, filed Oct. 13, 2010. The entire contents of these applications are incorporated herein by reference.

### BACKGROUND OF THE INVENTION

1. Field of the Invention

The present invention relates to a template to be used for supplying a processing solution to predetermined positions of a substrate, and a method for processing a substrate by using the template.

2. Description of Background Art

Recently, 3D integration technology to overlay devices three-dimensionally is proposed. In such 3D integration technology, multiple penetrating holes with fine diameters such as 100 μm or smaller, called TSVs (through silicon vias), are formed in a semiconductor wafer where multiple electronic circuits are formed on its surface (hereinafter referred to as a “wafer”), for example. After a penetrating electrode is formed in each penetrating hole, wafers overlaid vertically are electrically connected by such penetrating electrodes (see Japanese Laid-Open Patent Publication No. 2009-004722).

When forming such penetrating holes, etching is conducted using wet etching technology, for example. As for a method for performing fine local processing using wet etching, Japanese Laid-Open Patent Publication No. 2008-280558 describes a method in which puddles of an etching solution are formed on a surface of a wafer, and the tips of microprobes are dipped into the puddles of etching solution, and electric current is flowed through the microprobes to the wafer so that the etched regions are controlled.

The entire contents of these publications are incorporated herein by reference.

### SUMMARY OF THE INVENTION

According to one aspect of the present invention, a template for feeding a processing solution to predetermined positions of a substrate has multiple opening portions formed in positions on a front surface corresponding to the predetermined positions, flow channels penetrating from the opening portions to a back surface in a thickness direction for flowing a processing solution, first hydrophilic regions set to be hydrophilic around the opening portions on the front surface, and second hydrophilic regions set to be hydrophilic on inner surfaces of flow channels. The first hydrophilic regions are formed in positions corresponding to hydrophilic patterns set to be hydrophilic around the predetermined positions on a substrate surface.

According to another aspect of the present invention, a method for processing a substrate by feeding a processing solution to predetermined positions of the substrate uses a template having multiple opening portions formed in positions on its front surface that correspond to the predetermined positions, flow channels penetrating from the opening portions to a back surface in a thickness direction for flowing a processing solution, first hydrophilic regions set to be hydrophilic on the surface surrounding the opening portions, and second hydrophilic regions set to be hydrophilic on the inner surfaces of the flow channels, and using a substrate having hydrophilic patterns set to be hydrophilic around the predetermined positions on a front surface. The method includes a placement step for the front surface of the template and the front surface of the substrate to overlap in a way that positions of the first hydrophilic regions correspond to positions of the hydrophilic patterns, a solution filling step for feeding a processing solution to the flow channels to fill the processing solution between the first hydrophilic regions and the hydrophilic patterns, and a processing step for feeding the processing solution, which is fed to the flow channels, to the predetermined positions of the substrate, while adjusting positions of the template and the substrate so that the opening portions align with the predetermined positions, and the predetermined positions of the substrate are processed.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view outlining the structure of a wafer processing apparatus for implementing a wafer processing method according to an embodiment of the present invention;

FIG. 2 is a cross-sectional view outlining the structure of a wafer;

FIG. 3 is a view outlining the structure of a template;

FIG. 4 is a cross-sectional view outlining the structure of a template;

FIG. 5 is a view illustrating a hydrophilic pattern of a wafer in another embodiment;

FIG. 6 is a view illustrating hydrophilic regions of a template in another embodiment;

FIG. 7 is a view illustrating a hydrophilic pattern of a wafer in yet another embodiment;

FIG. 8 is a view illustrating hydrophilic regions of a template in yet another embodiment;

FIG. 9 is a view illustrating hydrophilic patterns of a wafer in yet another embodiment;

FIG. 10 is a view illustrating hydrophilic patterns of a wafer in yet another embodiment;

FIG. 11 is a flowchart showing main steps of a wafer processing;

FIG. 12 are views schematically illustrating a template and a wafer in each step of wafer processing: (a) shows a plating solution filled in a flow channel of a template; (b) shows overlapped template and wafer; (c) shows how a puddle of a plating solution is formed; (d) shows a plating solution filled between a first hydrophilic region and a hydrophilic pattern; (e) shows how a plating solution infiltrates a hole; (f) shows a plating solution filled in a hole; (g) shows restoration force exerted on the template; and (h) shows positional adjustment of the template and the wafer;

FIG. 13 is a cross-sectional view outlining the structure of a wafer in yet another embodiment;

FIG. 14 is a plan view outlining the structure of a wafer in yet another embodiment;

FIG. 15 is a cross-sectional view outlining the structure of a template in yet another embodiment;

FIG. 16 is a view illustrating how positional adjustment is conducted between a template and a wafer in yet another embodiment;

FIG. 17 is a cross-sectional view outlining the structure of a template in yet another embodiment;

FIG. 18 is a view outlining part of the structure of a template in yet another embodiment;

FIG. 19 is a cross-sectional view outlining the structure of a template in yet another embodiment;

FIG. 20 is a cross-sectional view outlining the structure of a wafer in yet another embodiment; and

FIG. 21 are views schematically illustrating a template and a wafer in each step of wafer processing in yet another embodiment: (a) shows an etching solution filled in a flow channel of a template; (b) shows overlapped template and wafer; (c) shows how a puddle of an etching solution is formed; (d) shows an etching solution filled between a first hydrophilic region and a hydrophilic pattern; (e) shows positional adjustment of the template and the wafer; (f) shows the wafer etched by an etching solution; and (g) shows a hole (scribe line) formed in the wafer.

### DETAILED DESCRIPTION OF THE EMBODIMENTS

The embodiments will now be described with reference to the accompanying drawings, wherein like reference numerals designate corresponding or identical elements throughout the various drawings.

In the drawings, sizes of each element are provided for the purpose of simplified technological understanding and do not exactly correspond to the actual sizes.

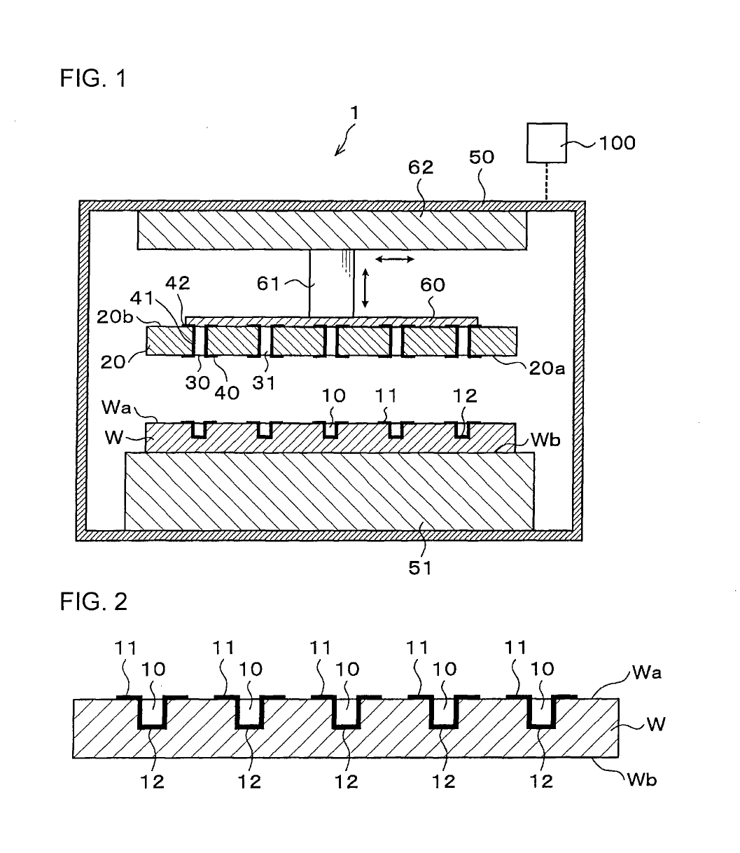

FIG. 1 is a cross-sectional view schematically showing the structure of wafer processing apparatus 1 according to the present embodiment to implement a processing method using a wafer as a substrate. The present embodiment describes wafer processing in which a plating solution is supplied into holes formed in a wafer so that the inside of the holes is plated.

Multiple holes 10 are formed in predetermined positions of front surface (Wa) of wafer (W) to be processed by wafer processing apparatus 1 of the present embodiment as shown in FIG. 2. Holes 10 are the same as penetrating holes with fine diameters, which are called TSVs in 3D integration technology. Namely, holes 10 do not penetrate through wafer (W) in a thickness direction in a wafer processing of the present embodiment, but when the back surface (Wb) side is polished to make wafer (W) thinner after the completion of wafer processing, holes 10 penetrate through wafer (W) in a thickness direction. Accordingly, penetrating holes are formed in wafer (W). Then, a plating solution is supplied into holes 10 to form electrodes in the present embodiment. Such electrodes become penetrating electrodes in 3D integration technology.

On front surface (Wa) of wafer (W), hydrophilic pattern 11 of hydrophilic property is formed around hole 10. Hydrophilic pattern 11 is a region that surrounds hole 10 and is set to be hydrophilic relative to other regions on front surface (Wa) of wafer (W). Therefore, when forming hydrophilic pattern 11, it is an option to process front surface (Wa) surrounding hole 10 to be hydrophilic, or to process other regions of front surface (Wa) to be hydrophobic, or to conduct both hydrophilic and hydrophobic treatments. Also, hydrophilic film 12 of hydrophilic property is formed on the inner and bottom surfaces of hole 10. Electronic circuits and a device layer (not shown) including wiring for power, ground and address signal which are connected to above-described penetrating electrodes are formed on front surface (Wa) of wafer (W).

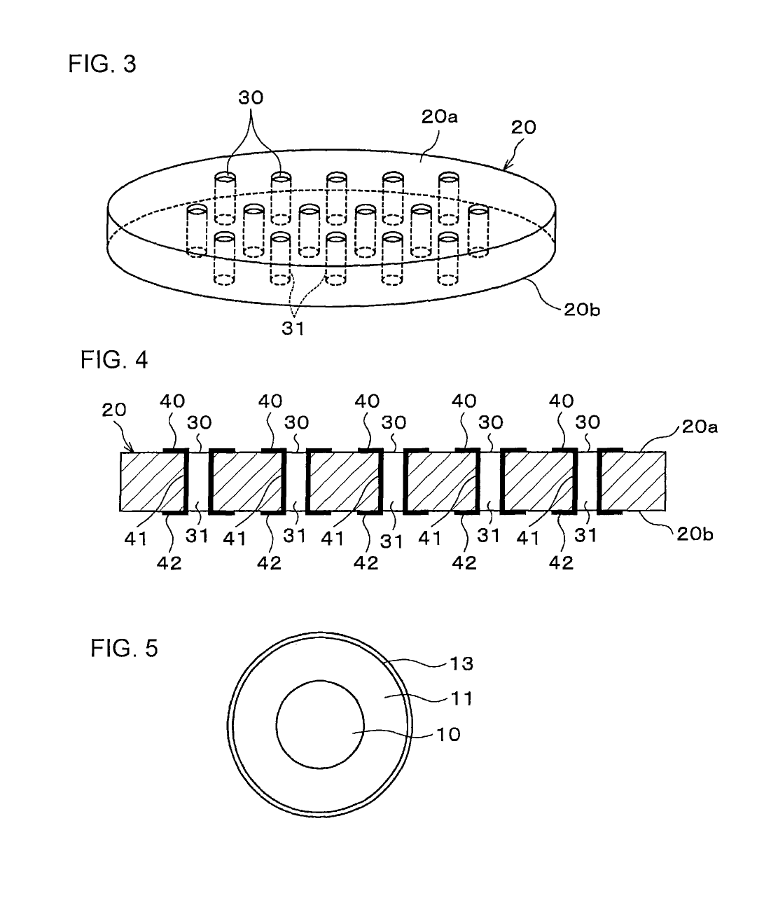

In wafer processing apparatus 1 of the present embodiment, template 20 with substantially a disc shape as shown in FIGS. 3 and 4 is used. Template 20 is made of silicon carbide (SiC), for example. Multiple opening portions 30 are formed on front surface (20a) of template 20. Such opening portions 30 are formed at positions corresponding to holes 10 of wafer (W). Opening portions 30 are formed by mechanical processing, or by conducting photolithographic and etching processing together so as to be positioned highly accurately.

In template 20, multiple flow channels 31 are formed to be connected to their respective opening portions 30 and for flowing a plating solution as a processing solution. Flow channels 31 penetrate through template 20 in a thickness direction, and extend to back surface (20b) of template 20.

On front surface (20a) of template 20, first hydrophilic region 40 of hydrophilic property is formed surrounding opening portion 30. First hydrophilic region 40 is a region that surrounds opening portion 30, and is set to be hydrophilic relative to the other regions on front surface (20a) of template 20. Therefore, when forming first hydrophilic region 40, it is an option to treat front surface (20a) surrounding opening portion 30 to be hydrophilic, or to treat other regions of front surface (20a) to be hydrophobic, or to conduct both hydrophilic and hydrophobic treatments. First hydrophilic region 40 is formed at a position corresponding to hydrophilic pattern 11 of wafer (W).

Also, second hydrophilic region 41 of hydrophilic property is formed on the inner surface of flow channel 31. Second hydrophilic region 41 is a region set to be hydrophilic, the same as with first hydrophilic region 40. Thus, it is an option to treat the inner surface of flow channel 31 to be hydrophilic when forming second hydrophilic region 41.

Moreover, third hydrophilic region 42 of hydrophilic property is formed around flow channel 31 on back surface (20b) of template 20. Third hydrophilic region 42 is a region around flow channel 31, and is set to be hydrophilic relative to the other regions of back surface (20b) of template 20. Therefore, when forming third hydrophilic region 42, it is an option to conduct hydrophilic treatment on back surface (20b) surrounding flow channel 31 or hydrophobic treatment on other regions of back surface (20b), or to conduct both hydrophilic and hydrophobic treatments.

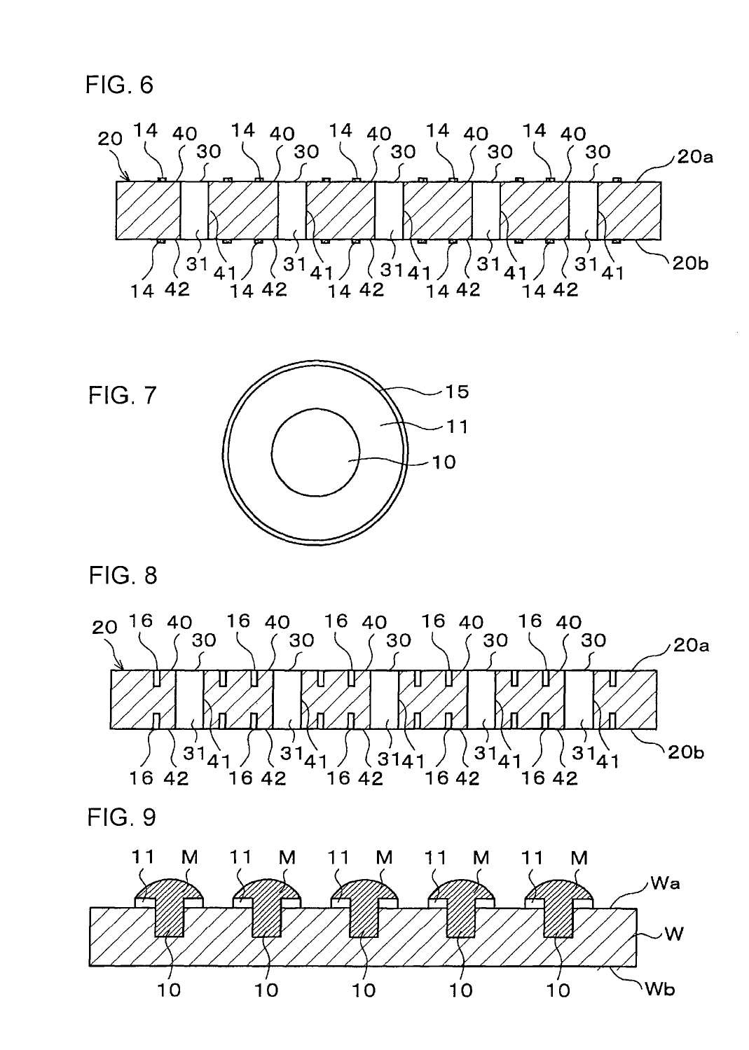

When hydrophilic pattern 11 is formed on front surface (Wa) of wafer (W), belt-like hydrophobic region 13 may be formed to surround hole 10 as shown in FIG. 5. In so forming, a plating solution supplied to the inner region of hydrophobic region 13 spreads its solution surface toward the border of hydrophobic region 13. Hydrophobic region 13 does not have to be a large area, and it is sufficient if hydrophobic region 13 surrounds the region of hydrophilic pattern 11. Thus, the size of the treatment regions on front surface (Wa) of wafer (W) is reduced. The same applies when a hydrophilic region is formed on template 20 as shown in FIG. 6. Hydrophobic regions 14 are formed to surround flow channel 31 on front surface (20a) and back surface (20b) of template 20. The portions surrounding an opening portion on front surface (20a) and back surface (20b) of template 20 become first hydrophilic region 40 and third hydrophilic region 42 respectively, and the inner surface of flow channel 31 becomes second hydrophilic region 41.

Alternatively, instead of forming hydrophobic region 13 in wafer (W), concave 15 as shown in FIG. 7 may be formed. Concave 15 is formed to surround hole 10, the same as with hydrophobic region 13. The solution surface of a plating solution supplied to the inside part of concave 15 spreads at a certain angle of contact, and makes a greater angle of contact at the edge of concave 15. The solution surface cannot pass concave 15 and stays inside concave 15. In so setting, the region to which a plating solution spreads is controlled without conducting a hydrophilic or hydrophobic treatment on front surface (Wa) of wafer (W). Such a phenomenon of suppressing the spreading of a plating solution by concave 15 is known as a pinning effect. Namely, though the inside region of concave 15 has the same property as its outside region, the inside region of concave 15 works as hydrophilic pattern 11 because of the pinning effect of concave 15. Since a lithographic technique is used for forming concave 15, no special procedure is necessary.

The same applies when forming hydrophilic regions (41˜43) for template 20. As shown in FIG. 8, concaves 16 are formed to surround flow channel 31 on front surface (20a) and back surface (20b) of template 20. The portions surrounding an opening portion on front surface (20a) and back surface (20b) of template 20 become first hydrophilic region 40 and third hydrophilic region 42 respectively, and the inner surface of flow channel 31 becomes second hydrophilic region 41. Since a hydrophilic or hydrophobic treatment is not necessary to be conducted on front surface (20a) and back surface (20b) of template 20, hydrophilic regions (41˜43) are formed using a lithographic technique.

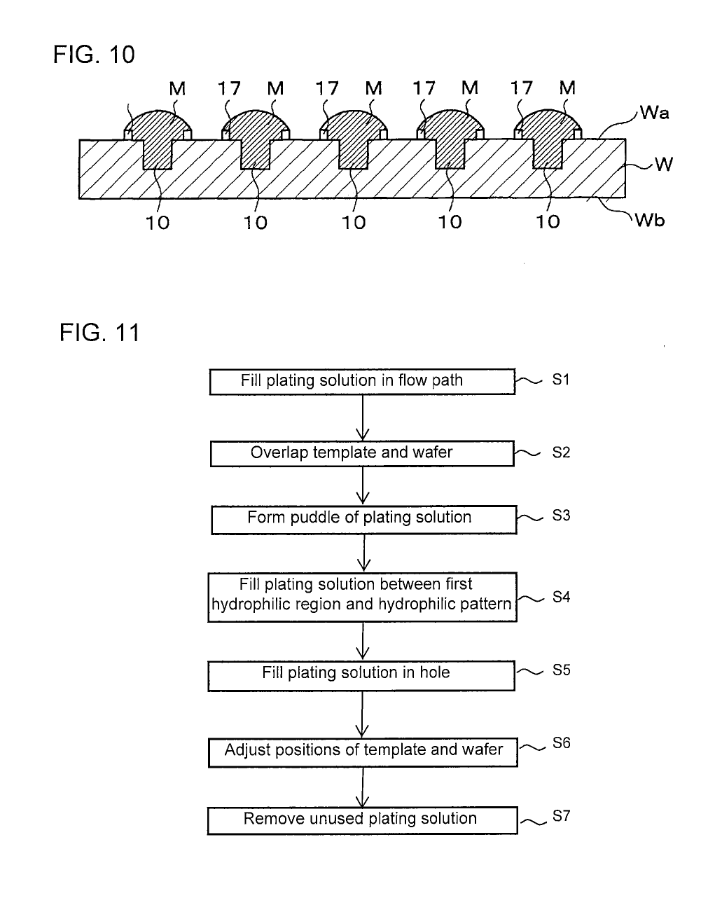

Also, to achieve a pinning effect, it is sufficient if there is a height difference between a hydrophilic region and its surrounding region. The structure of such a height difference is not limited to being a concave. As for a treatment example of front surface (Wa) of wafer (W), if hydrophilic pattern 11 protrudes from its surrounding portions, the spreading of the solution surface stops at the shoulder as shown in FIG. 9. Alternatively, if convex 17 is formed to surround hole 10 as shown in FIG. 10, the spreading of the solution surface stops at the shoulder of convex 17. Especially, when important thin film is formed on front surface (Wa) of wafer (W) and a concave cannot be formed to have sufficient depth, the above methods are effective. Such protrusions and convexes are formed when a thin film prepared by CVD or the like is patterned using a lithographic technique. The same applies to template 20. Namely, instead of forming concaves, it is an option to set hydrophilic regions (40, 42) to protrude themselves, or to form convexes to surround them when forming first hydrophilic region 40 and third hydrophilic region 42.

Moreover, when concaves (15, 16) and convex 17 are formed to achieve a pinning effect, or when hydrophilic pattern 11 and hydrophilic regions (40, 42) are set to protrude, such procedures may be combined with a hydrophilic treatment and a hydrophobic treatment conducted on front surface (Wa) of wafer (W), and on front surface (20a) and back surface (20b) of template 20. The spreading of the solution surface is further controlled by such combinations.

As shown in FIG. 1, wafer processing apparatus 1 of the present embodiment has processing chamber 50 to accommodate wafer (W) inside. On the bottom of processing chamber 50, table 51 to place wafer (W) is provided. A vacuum chuck or the like is used for table 51, for example. Wafer (W) is placed horizontally on table 51 with front surface (Wa) of wafer (W) facing upward.

Holding member 60 to hold template 20 is positioned above table 51. Holding member 60 holds template 20 with front surface (20a) of template 20 facing downward. Then, template 20 held by holding member 60 is positioned so that its front surface (20a) faces front surface (Wa) of wafer (W) on table 51.

Holding member 60 is supported by shaft 61 to be held by moving mechanism 62 formed on the ceiling of processing chamber 50. Because of moving mechanism 62, template 20 and holding member 60 are movable horizontally and vertically.

In addition, a solution supply mechanism (not shown) is provided in processing chamber 50 to supply a plating solution from the back-surface (20b) side of template 20 to flow channels 31. As for a solution supply method, various methods such as using nozzles or supply pipes are listed.

Control unit 100 is provided for the above wafer processing apparatus 1. Control unit 100 is a computer, for example, and has a program storage section (not shown). The program storage section stores programs to implement later-described wafer processing in wafer processing apparatus 1. Here, such programs may be those stored in a computer readable storage medium such as a hard disc (HD), flexible disc (FD), compact disc (CD), magneto-optical disc (MO) or memory card, and installed in control unit 100 from the memory medium.

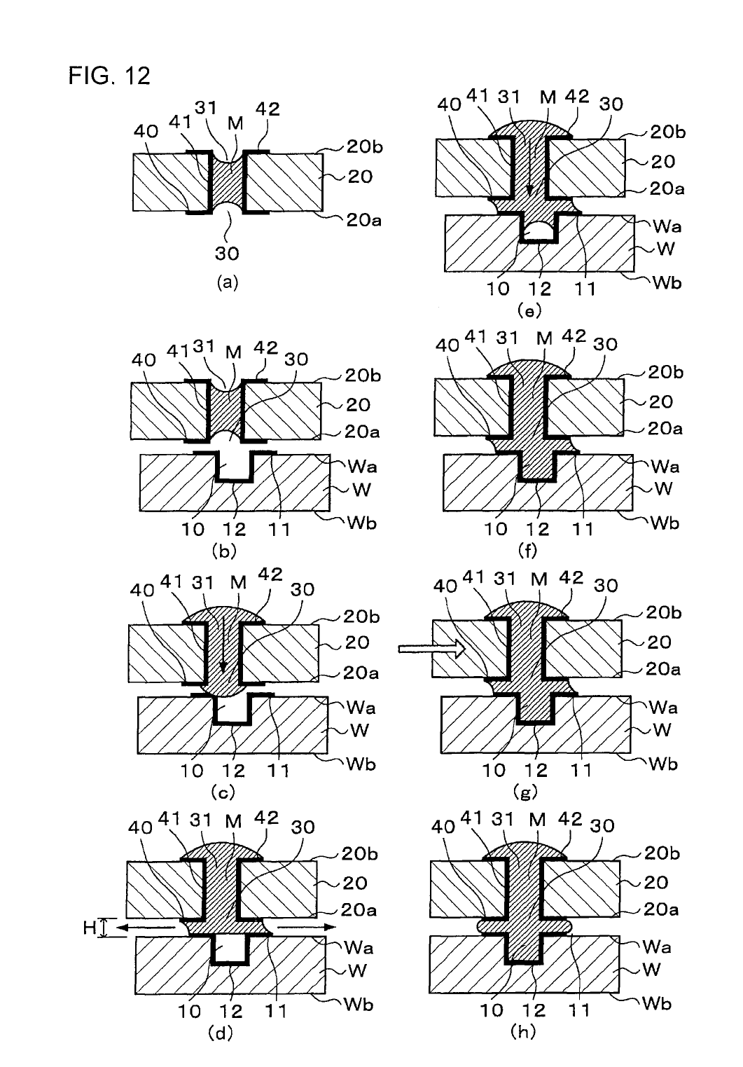

Next, processing of wafer (W) is described using wafer processing apparatus 1 structured as above. FIG. 11 is a flowchart showing the main steps of wafer processing. FIG. 12 are views schematically illustrating template 20 and wafer (W) in each step of wafer processing. For the purpose of simplified technological understanding, FIG. 12 show part of template 20 (one flow channel 31) and part of wafer (W) (vicinity of one hole 10).

First, outside wafer processing apparatus 1, plating solution (M) is filled in advance in flow channel 31 of template 20 as shown in FIG. 12(a) (step (S1) in FIG. 11). To fill plating solution (M), first, plating solution (M) is supplied to the back-surface (20b) side of template 20, for example. Because flow channel 31 has a fine diameter, and because third hydrophilic region 42 is formed around flow channel 31 and second hydrophilic region 41 is formed on the inner surface of flow channel 31, plating solution (M) supplied to the back-surface (20b) side infiltrates flow channel 31 through capillary action. After that, extra plating solution remaining on back surface (20b) of template 20 is removed. Accordingly, plating solution (M) is filled in flow channel 31 as shown in FIG. 12(a). Although both ends of flow channel 31 are open, plating solution (M) is kept in flow channel 31 because of surface tension of plating solution (M). Therefore, spilling of plating solution (M) is prevented while template 20 is transported. Various plating solutions may be used as plating solution (M). The present embodiment is described using plating solution (M) containing copper sulfate pentahydrate CuSO₄ and sulfuric acid. It is an option to use a plating solution containing silver nitrate, aqueous ammonia and glucose, an electroless copper plating solution or the like. In the present embodiment, plating solution (M) is supplied in advance to template 20 before template 20 is transported to wafer processing apparatus 1. When using a method for supplying plating solution (M) in advance, it is an option to supply plating solution (M) under reduced pressure so that plating solution (M) infiltrates flow channel 31 sufficiently even if flow channel 31 is narrow, or to apply spin coating or the like so that plating solution (M) is supplied efficiently. Alternatively, if there is a way to supply plating solution (M) efficiently inside wafer processing apparatus 1, it is not necessary to supply plating solution (M) to template 20 in advance.

Next, template 20 with plating solution (M) filled in flow channel 31 is transported into wafer processing apparatus 1. Since plating solution (M) is held in flow channel 31 because of surface tension as described above, plating solution (M) does not flow out from flow channel 31 while template 20 is being transported. Here, to prevent the outflow of plating solution (M) even more securely, sealing strips (not shown) may be provided for template 20.

When template 20 is transported to wafer processing apparatus 1, wafer (W) is also transported to wafer processing apparatus 1.

In wafer processing apparatus 1, template 20 is held by holding member 60 and wafer (W) is placed on table 51. Template 20 is held by holding member 60 with its front surface (20a) facing downward. Wafer (W) is placed on table 51 with its front surface (Wa) facing upward. Then, template 20 is lowered to a predetermined position while its horizontal direction is adjusted by moving mechanism 62. When the position of template 20 is adjusted by moving mechanism 62, an optical sensor (not shown), for example, is used. Then, front surface (20a) of template 20 and front surface (Wa) of wafer (W) overlap in a way that positions of first hydrophilic region 40 of template 20 and hydrophilic pattern 11 of wafer (W) correspond to each other as shown in FIG. 12(b) (step (S2) in FIG. 11). Here, it is not necessary for the position of first hydrophilic region 40 to align exactly with the position of hydrophilic pattern 11. When their positions are slightly shifted, namely, the position of opening portion 30 is slightly shifted from the position of hole 10, the positions of template 20 and wafer (W) are adjusted in later-described step (S6). In addition, in the example shown in FIG. 12(b), space with a fine distance is formed between template 20 and wafer (W). However, template 20 and wafer (W) may also be positioned to adhere to each other.

Next, using a solution supply method such as a nozzle (not shown), plating solution (M) is supplied to the back-surface (20b) side of template 20 as shown in FIG. 12(c). Then, plating solution (M) in flow channel 31 flows downward vertically. The lower surface of plating solution (M) curves downward near opening portion 30, forming a so-called solution puddle (step (S3) in FIG. 11). In the present embodiment, a solution puddle is formed after template 20 and wafer (W) overlap. However, if template 20 is positioned over wafer (W), template 20 and wafer (W) may overlap after a solution puddle is formed.

Plating solution (M) near opening portion 30 spreads horizontally because of capillary action as shown in FIG. 12(d). Namely, plating solution (M) infiltrates between first hydrophilic region 40 of template 20 and hydrophilic pattern 11 of wafer (W). Accordingly, plating solution (M) is filled between first hydrophilic region 40 and hydrophilic pattern 11 (step (S4) in FIG. 11). Plating solution (M) spreads only between first hydrophilic region 40 and hydrophilic pattern 11, and does not spread beyond those portions.

At that time, template 20 rises relative to wafer (W) due to surface tension or the like of plating solution (M) filled between first hydrophilic region 40 and hydrophilic pattern 11. Accordingly, space with predetermined distance (H) is formed between template 20 and wafer (W). That makes template 20 horizontally movable relative to wafer (W). At that time, pressure is spread on the entire fluid due to the Laplace pressure exerted on the surface of plating solution (M) exposed to the outside between template 20 and wafer (W) and on the surface of plating solution (M) protruding from the back surface of template 20. According to Pascal's principle, such pressure works on template 20 to make it to rise relative to wafer (W).

Predetermined distance (H) is set at a distance for adjusting the positions of template 20 and wafer (W) when template 20 moves as described later. Here, as described later, restoration force is exerted on template 20 due to surface tension of plating solution (M) filled between first hydrophilic region 40 and hydrophilic pattern 11, and the positions of template 20 and wafer (W) are adjusted. Predetermined distance (H) is set to secure such restoration force, namely, surface tension of plating solution (M). Specifically, predetermined distance (H) can be adjusted according to the amount of plating solution (M) to be supplied, areas of hydrophilic pattern 11, first hydrophilic region 40 and third hydrophilic region 42, the weight of template 20 itself and the like. Especially, since third hydrophilic region 42 is positioned on back surface (20b) of template 20 where no device layer or the like is formed, the margin of its adjustable area is great. If desired distance (H) is obtained, third hydrophilic region 42 does not have to be formed. Namely, the size of plating solution (M) protruding from back surface (20b) of template 20 will have substantially the same diameter as that of flow channel 31. Those effects above also apply when pure water is supplied to a position facing a scribe line or the like in embodiments described later.

After that, more plating solution (M) is supplied to the back-surface (20b) side of template 20. Accordingly, plating solution (M) near opening portion 30 flows downward vertically due to capillary action as shown in FIG. 12(e), and infiltrates hole 10 of wafer (W). Then, plating solution (M) is filled in hole 10 as shown in FIG. 12(f) (step (S5) in FIG. 11).

At that time, due to surface tension of plating solution (M) filled between first hydrophilic region 40 and hydrophilic pattern 11 as described above, restoration force (arrow in FIG. 12(g)) works on template 20 to cause movement of template 20 as shown in FIG. 12(g). Even when positions of opening portion 30 of template 20 and hole 10 of wafer (W) are shifted from each other, template 20 is moved by the above restoration force so that opening portion 30 faces hole 10. Thus, the positions of template 20 and wafer (W) are adjusted as shown in FIG. 12(h) (step (S6) of FIG. 11). Accordingly, plating solution (M) is properly filled in a predetermined position of wafer (W), namely in hole 10. Here, steps are described using FIG. 12(d) to FIG. 12(g) in that order, but actually, those phenomena occur substantially simultaneously.

Then, the plating solution remaining on back surface (20b) of template 20 is removed as unused plating solution (step (S7) in FIG. 11).

Next, electrical voltage is applied to plating solution (M) in hole 10 of wafer (W) using a power-source device (not shown). Reaction of plating solution (M) in hole 10 occurs accordingly and copper is deposited in hole 10 to form an electrode. Furthermore, when wafer (W) is thinned when its back-surface (Wb) side is polished, hole 10 becomes a penetrating hole, making the electrode in hole 10 a penetrating electrode.

According to the above embodiment, since plating solution (M) is filled in advance in flow channel 31 of template 20 in step (S1), the amount of plating solution (M) to be supplied to flow channel 31 in and after step (S3) is reduced.

Also, after a puddle of plating solution (M) is formed in step (S3), plating solution (M) is filled between first hydrophilic region 40 and hydrophilic pattern 11 in step (S4). Because of surface tension or the like of filled plating solution (M), template 20 rises relative to wafer (W), thus becoming horizontally movable relative to wafer (W). Under such conditions, plating solution (M) is filled in hole 10 in step (S5), and restoration force that moves template 20 is exerted on template 20 due to surface tension of plating solution (M) filled between first hydrophilic region 40 and hydrophilic pattern 11. Even when positions of opening portion 30 of template 20 and hole 10 of wafer (W) are shifted from each other, template 20 is moved by the above restoration force so that opening portion 30 faces hole 10. Thus, in step (S6), the positions of template 20 and wafer (W) are adjusted highly accurately. As described, the degree of accuracy is enhanced when adjusting the positions of template 20 and wafer (W), even when hole 10 has such a fine diameter. Accordingly, plating solution (M) is properly supplied from flow channel 31 of template 20 through opening portion 30 to hole 10 of wafer (W). Moreover, opening portion 30 itself is formed with high positional accuracy as described above, allowing plating solution (M) to be supplied to hole 10 with high positional accuracy. Therefore, hole 10 is properly plated and a proper electrode is formed in hole 10.

In addition, since positional adjustment of template 20 and wafer (W) is conducted in step (S6), it is unnecessary to strictly align their positions when template 20 and wafer (W) overlap in step (S2). Thus, moving mechanism 62 of wafer processing apparatus 1 does not have to be highly functional, allowing it to be simple and inexpensive. Also, complex control of moving mechanism 62 is not required.

In the embodiment above, opening portion 30 of template 20 is formed to correspond to hole 10 of wafer (W). It is an option to form an opening portion to face a scribe line of wafer (W). Scribe lines are lines to be used when wafer (W) is cut into multiple semiconductor chips. Usually, elements and wiring are not formed on scribe lines or in their vicinity. Thus, semiconductor chips are not affected if those regions are set as hydrophilic regions and pure water is supplied to such regions as described later.

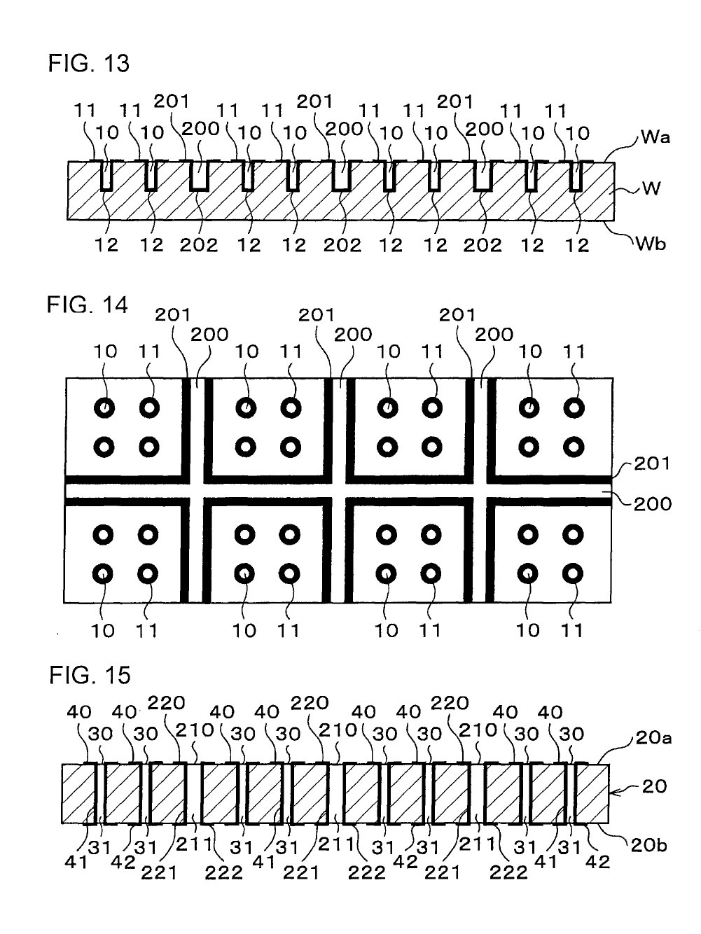

In the present embodiment, scribe lines 200 are formed in addition to multiple holes 10 in predetermined positions of front surface (Wa) of wafer (W) as shown in FIGS. 13 and 14. Scribe lines 200 do not penetrate through wafer (W) in a thickness direction in the present embodiment, but they penetrate through wafer (W) when wafer (W) is thinned after the back surface (Wb) side of wafer (W) is polished when wafer processing is completed. Then, wafer (W) is divided along scribe lines 200 to form multiple semiconductor chips.

Hydrophilic patterns 201 are formed around scribe lines 200 on front surface (Wa) of wafer (W). The same as hydrophilic pattern 11 formed surrounding hole 10, hydrophilic pattern 201 is a region around scribe line 200, and is set to be hydrophilic relative to other regions on front surface (Wa) of wafer (W) (excluding hydrophilic pattern 11). Thus, when forming hydrophilic pattern 201, a hydrophilic treatment may be conducted around scribe line 200 on front surface (Wa), or a hydrophobic treatment may be conducted in other regions (excluding hydrophilic pattern 11) of front surface (Wa). Alternatively, a concave may also be formed to achieve a pinning effect. Also, hydrophilic film 202 of hydrophilic property is formed on the inner and bottom surfaces of scribe line 200. In the present embodiment, a ditch for a scribe line 200 is formed in advance on wafer (W), but it is an option to form only hydrophilic pattern 201 without forming a ditch. Hydrophilic pattern 201 is not necessarily a straight line along scribe line 200, and it may be formed inside or around scribe line 200, taking any shape.

Also, in addition to opening portions 30, other multiple opening portions 210 are formed on front surface (20a) of template 20 as shown in FIG. 15. Those opening portions 210 are formed in positions corresponding to scribe lines 200 of wafer (W). The same as with opening portions 30, since opening portions 210 are also formed by mechanical processing or by conducting lithographic and etching processing together, they are formed in highly accurate positions.

In template 20, multiple flow channels 211 are formed to be connected to opening portions 210 and to flow pure water as a processing solution. Flow channels 211 penetrate through template 20 in a thickness direction and extend to back surface (20b) of template 20.

On front surface (20a) of template 20, first hydrophilic region 220 of hydrophilic property is formed around opening portion 210. First hydrophilic region 220 is a region around opening portion 210, and is set to be hydrophilic relative to other regions (excluding first hydrophilic region 40) on front surface (20a) of template 20. Thus, when forming first hydrophilic region 220, a hydrophilic treatment may be conducted on front surface (20a) around opening portion 210 or a hydrophobic treatment may be conducted in other regions (excluding first hydrophilic region 40) of front surface (20a), or both hydrophilic and hydrophobic treatments may be conducted. In addition, first hydrophilic region 220 is formed in a position corresponding to hydrophilic pattern 201 of wafer (W).

Also, second hydrophilic region 221 of hydrophilic property is formed on the inner surface of flow channel 211. Second hydrophilic region 221 is a region set to be hydrophilic, the same as first hydrophilic region 220. Thus, when forming second hydrophilic region 41, a hydrophilic treatment may be conducted on the inner surface of flow channel 211.

Moreover, third hydrophilic region 222 of hydrophilic property is formed to surround flow channel 211 on back surface (20b) of template 20. Third hydrophilic region 222 is a region around flow channel 211, and is set to be hydrophilic relative to other regions (excluding third hydrophilic region 42) on back surface (20b) of template 20. Thus, when forming third hydrophilic region 222, a hydrophilic treatment may be conducted on back surface (20b) around flow channel 211, or a hydrophobic treatment may be conducted in other regions (excluding third hydrophilic region 42) of back surface (20b), or both hydrophilic and hydrophobic treatments may be conducted.

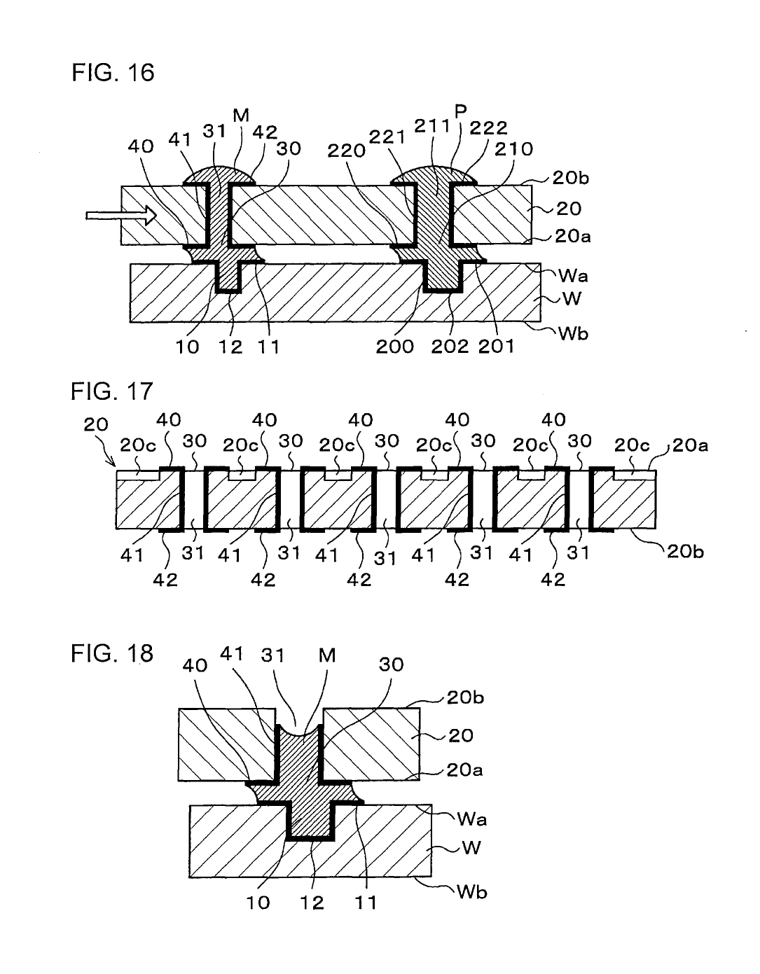

Under such conditions, plating solution (M) is filled in flow channel 31 of template 20 while pure water is filled in flow channel 211 in step (S1). Then, in step (S2), front surface (20a) of template 20 and front surface (Wa) of wafer (W) overlap in a way that positions of first hydrophilic region 40 and hydrophilic pattern 11 correspond to each other and positions of first hydrophilic region 220 and hydrophilic pattern 201 correspond to each other. After that, in step (S3), plating solution (M) is supplied to flow channel 31 and pure water is supplied to flow channel 211 from the back-surface (20b) side of template 20. In doing so, in step (S4), plating solution (M) is filled between first hydrophilic region 40 and hydrophilic pattern 11, and pure water is filled between first hydrophilic region 220 and hydrophilic pattern 201. After that, in step (S5), plating solution (M) is filled in hole 10 and pure water is filled in scribe line 200. Then, in step (S6), the positions of template 20 and wafer (W) are adjusted as shown in FIG. 16. At that time, in addition to restoration force caused by surface tension of plating solution (M), another restoration force caused by surface tension of pure water is exerted on template 20. After that, in step (S7), the unused plating solution and pure water remaining on back surface (20b) of template 20 are removed.

Since the effects of pure water (P) in steps (S1)˜(S7) of the present embodiment are the same as those of plating solution (M) in steps (S1)˜(S7) of the above embodiment, a detailed description is omitted here.

In the present embodiment, in addition to the restoration force caused by surface tension of plating solution (M), another restoration force caused by surface tension of pure water (P) is exerted on template 20 in step (S6). Also, the effects of Pascal's principle are the same. Thus, the force to raise template 20 from wafer (W) increases even if template 20 has a certain level of weight. Moreover, since the restoration force increases, even if the shifted amount is greater between positions of opening portion 30 of template 20 and hole 10 of wafer (W) (the shifted amount is the same between positions of opening portion 210 and scribe line 200), template 20 is moved smoothly. Therefore, positional adjustment of template 20 and wafer (W) is performed properly. In the above embodiment, opening portion 210 is formed in a position of template 20 facing scribe line 200. However, that is not the only option. By selecting locations of a front surface of a semiconductor chip that do not cause any problem when in contact with pure water, opening portions may be formed in template 20 so that pure water is supplied to desired regions.

In the above embodiment, plating solution (M) and pure water (P) are supplied simultaneously to template 20. However, that is not the only option, and pure water (P) may be supplied first. If positional adjustment of template 20 and wafer (W) is conducted in advance using surface tension of pure water (P), and then plating solution (M) is supplied subsequently, plating solution (M) is more accurately supplied to hole 10 of wafer (W). When plating solution (M) is supplied, at least opening portion 30 of template 20 and hole 10 of wafer (W) need to be aligned with each other to a certain degree. However, since semiconductor devices are becoming finer and holes 10 of wafer (W) are also becoming finer, it is difficult to align their positions. Thus, opening portion 210 of template 20 and opposing hydrophilic pattern 201 are preferred to be formed larger than hole 10 of wafer (W). When template 20 and wafer (W) overlap, since it is sufficient to align only opening portion 210 and hydrophilic pattern 201, positional control is simplified. After that, another positional adjustment is conducted using pure water (P) so that opening portion 30 of template 20 aligns with hole 10 of wafer (W).

In addition, pure water (P) filled in scribe line 200 works as a coolant for controlling temperature rises in plating solution (M) and template 20 when forming an electrode by applying voltage to plating solution (M) in hole 10.

In the present embodiment, pure water (P) is filled in scribe line 200 through flow channel 211. However, it is an option to fill plating solution (M) in scribe line 200 as well as in hole 10. In such a case as well, plating solution (M) in scribe line 200 works the same as pure water, and the positional adjustment of template 20 and wafer (W) is properly performed. Here, when voltage is applied to plating solution (M) in hole 10 to form an electrode, voltage is not applied to plating solution (M) in scribe line 200 so that no electrode is formed in scribe line 200.

In addition, scribe line 200 is formed in a straight line on a planar view as shown in FIG. 14. However, it may be formed in a curved line or in a zigzag pattern. In such cases, both hydrophilic pattern 201 on wafer (W) and first hydrophilic region 220 on template 20 increase their lengths. Accordingly, surface tension of pure water (P) filled between first hydrophilic region 220 and hydrophilic pattern 201 increases, causing the restoration force on template 20 to increase. Therefore, positional adjustment of template 20 and wafer (W) is performed even more properly.

In the above embodiment, regions where first hydrophilic regions 40 are not formed on front surface (20a) of template 20 may be recessed with respect to first hydrophilic regions 40 to form grooves (20c) as shown in FIG. 17. In such a case, contact angles at first hydrophilic region 40 and hydrophilic pattern 11 become greater. Thus, in step (S4), plating solution (M) filled between first hydrophilic region 40 and hydrophilic pattern 11 is securely prevented from spreading beyond first hydrophilic region 40. Accordingly, since surface tension of plating solution (M) is secured between first hydrophilic region 40 and hydrophilic pattern 11, positional adjustment of template 20 and wafer (W) is properly performed. If first hydrophilic region 220 shown in FIG. 15 is further formed on front surface (20a) of template 20, groove (20c) is formed in a region where first hydrophilic regions (40, 220) are not formed.

In the above embodiment, second hydrophilic region 41 is formed on the entire inner surface of flow channel 31 of template 20, but it may be formed from opening portion 30 up to a certain level of the inner surface of flow channel 31 as shown in FIG. 18. In such a case, when plating solution (M) is filled in hole 10 in step (S5), the solution surface of plating solution (M) is at the height to which second hydrophilic region 41 is formed as shown in FIG. 18. Namely, plating solution (M) is not present beyond second hydrophilic region 41 in the upper portion of flow channel 31. When plating solution (M) is further supplied to the back-surface (20b) side of template 20, plating solution (M) further infiltrates flow channel 31. Accordingly, more plating solution (M) infiltrates and fills between first hydrophilic region 40 and hydrophilic pattern 11, causing the surface tension of plating solution (M) to increase. Thus, in subsequent step (S6), greater restoration force is exerted on template 20, and positional adjustment of template 20 and wafer (W) is performed more properly.

In the above embodiment, template 20 may be oscillated in steps (S3)˜(S6). In such a case, moving mechanism 62 of wafer processing apparatus 1 works as a driving mechanism, and template 20 is oscillated in a state where template 20 and wafer (W) overlap. In doing so, plating solution (M) tends to infiltrate hole 10 and between first hydrophilic region 40 and hydrophilic pattern 11. Also, template 20 is easier to move, making it easier to adjust the positions of template 20 and wafer (W). Template 20 may be oscillated in all steps (S3)˜(S6) or only in any step.

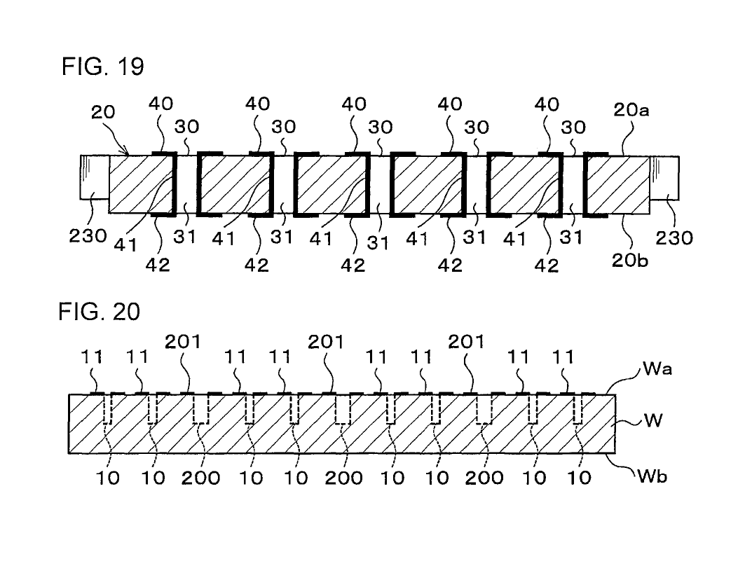

Driving mechanism 230 may be provided to template 20 as shown in FIG. 19 instead of using moving mechanism 62 as a driving mechanism. Multiple driving mechanisms 230 may be provided on the outer surface of template 20, for example, at equal intervals in a circumferential direction.

In the above embodiment, plating is described as a wafer processing where plating solution (M) is supplied into hole 10 of wafer (W) so that the inside of hole 10 is plated. However, an embodiment of the present invention applies when conducting other processing using other processing solutions.

In the above embodiment, a solution for forming insulative film, for example, may be used as a processing solution to form insulative film in hole 10 of wafer (W). Such insulative film is formed prior to the above-described plating processing, for example. As for film-forming solutions, an electrocoating polyimide solution, for example, is used. Also, in the above embodiment, hole 10 and scribe line 200 of wafer (W) may be cleansed using a cleaning solution or pure water as a processing solution, for example. Such cleansing is conducted after the above-described plating process or after a later-described etching process.

Moreover, etching is performed on wafer (W) using an etching solution as a processing solution, for example. As shown in FIG. 20, hydrophilic patterns (11, 201) are formed on front surface (Wa) of wafer (W) of the present embodiment. Hydrophilic patterns (11, 201) are formed in their respective positions surrounding hole 10 and scribe line 200. Since those hydrophilic patterns (11, 201) are the same as those shown in FIGS. 2 and 13, their detailed description is omitted here. Since hole 10 and scribe line 200 are formed by etching wafer (W) in the present embodiment, hole 10 and scribe line 200 are not formed in wafer (W) before the etching process.

Also, template 20 in the present embodiment is the same as that shown in FIG. 15, and its detailed description is omitted here.

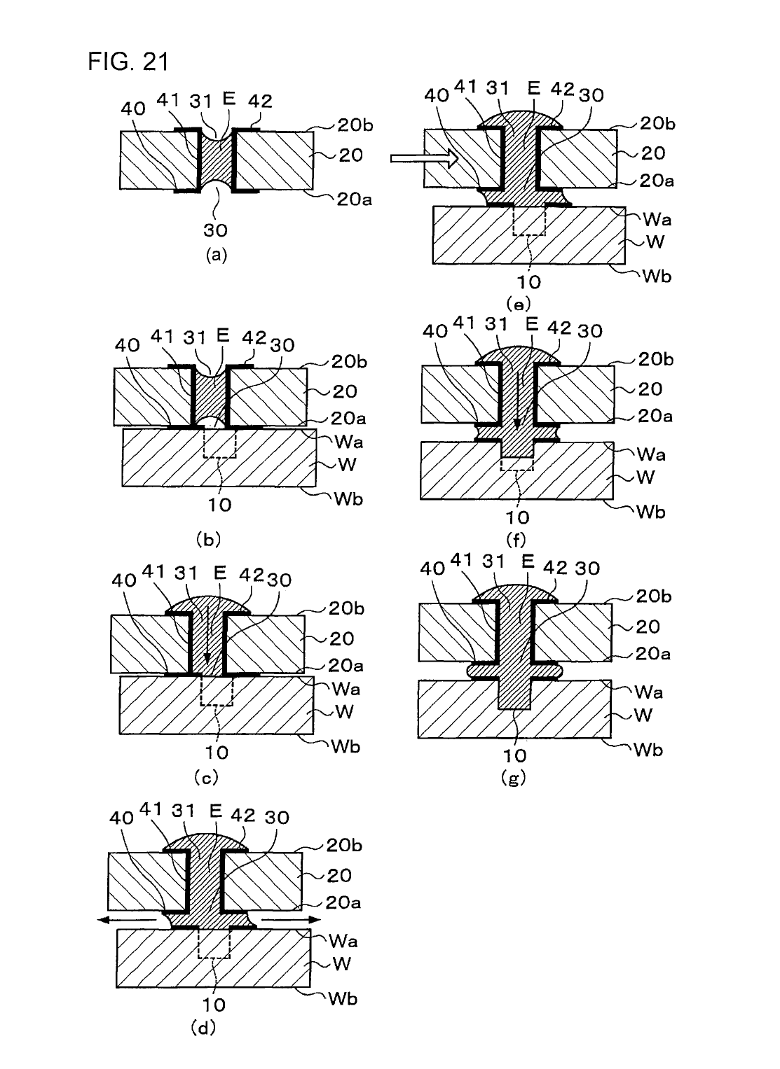

Next, an etching process of wafer (W) according to the present embodiment is described. FIG. 21 schematically illustrate template 20 and wafer (W) in each step of wafer processing. In FIG. 21, for the purpose of simplified technological understanding, part of template 20 (vicinity of one flow channel 31) and part of wafer (W) (vicinity of one hole 10) are shown. In the present embodiment, the effects of etching solution (E) on flow channel 31 and hole 10 are the same as the effects of etching solution (E) on other flow channel 211 and scribe line 200.

First, as shown in FIG. 21(a), etching solution (E) is filled in flow channel 31 of template 20 while etching solution (E) is also filled in flow channel 211. Since filling etching solution (E) in flow channels (31, 211) is conducted outside wafer processing apparatus 1, which is the same as in step (S1) described above, a detailed description is omitted here.

Then, as shown in FIG. 21(b), front surface (20a) of template 20 and front surface (Wa) of wafer (W) overlap in wafer processing apparatus 1 in a way that positions of first hydrophilic region 40 and hydrophilic pattern 11 correspond to each other while positions of first hydrophilic region 220 and hydrophilic pattern 201 correspond to each other. Since a placement step for template 20 and wafer (W) is the same as above-described step (S2), its description is omitted here.

Next, as shown in FIG. 21(c), etching solution (E) is supplied to the back surface (20b) side of template 20. Then, etching solution (E) near opening portion 30 spreads horizontally due to capillary action as shown in FIG. 21(d). Namely, etching solution (E) infiltrates between first hydrophilic region 40 of template 20 and hydrophilic pattern 11 of wafer (W). In the same manner, etching solution (E) infiltrates between first hydrophilic region 220 and hydrophilic pattern 201 as well. Accordingly, etching solution (E) is filled between first hydrophilic region 40 and hydrophilic pattern 11 and between first hydrophilic region 220 and hydrophilic pattern 201 (hereinafter, may be referred to as “between first hydrophilic regions (40, 220) and hydrophilic patterns (11, 201)”). Etching solution (E) spreads only between first hydrophilic regions (40, 220) and hydrophilic patterns (11, 201) that are set to be hydrophilic, and does not spread beyond those portions.

At that time, template 20 rises relative to wafer (W) due to surface tension or the like of etching solution (E) filled between first hydrophilic regions (40, 220) and hydrophilic patterns (11, 201). Accordingly, template 20 becomes horizontally movable relative to wafer (W).

Next, due to surface tension of etching solution (E) filled between first hydrophilic regions (40, 220) and hydrophilic patterns (11, 201) described above, restoration force is exerted on template 20 to move template 20 as shown in FIG. 21(e) (arrow in FIG. 21(e)). Accordingly, even if positions of opening portion 30 of template 20 and hole 10 of wafer (W) are shifted from each other (positions of opening portion 210 and scribe line 200 are also shifted from each other at that time), template 20 moves because of the above restoration force so that opening portion 30 faces hole 10 while opening portion 210 faces scribe line 200. Accordingly, positional adjustment of template 20 and wafer (W) is achieved.

Next, etching solution (E) is further supplied to the back-surface (20b) side of template 20 as shown in FIG. 21(f). Then, etching solution (E) in flow channels (31, 211) flow downward due to capillary action, and wafer (W) is etched. At that time, since etching solution (E) shows high surface tension due to capillary action, wafer (W) is smoothly etched. Thus, wafer (W) is etched to a predetermined depth by etching solution (E) as shown in FIG. 21(g), forming hole 10. In the same manner, scribe line 200 is also formed in wafer (W).

After etching is performed on wafer (W) as described above, and hole 10 and scribe line 200 are formed, etching solution (E) is removed.

In the present embodiment as well, the same effects as above are achieved. Namely, the positions of template 20 and wafer (W) are adjusted properly so that etching solution (E) is supplied with high positional accuracy to positions for forming hole 10 and scribe line 200. Therefore, hole 10 and scribe line 200 are properly formed in wafer (W).

In the above embodiment, first hydrophilic regions (40, 220), second hydrophilic regions (41, 221) and third hydrophilic regions (42, 222) are formed around flow channels (31, 211) of template 20 to set those regions to be hydrophilic, while hydrophilic patterns (11, 201) and hydrophilic films (12, 202) are formed around hole 10 and scribe line 200 of wafer (W) to set those portions to be hydrophilic. By contrast, if hydrophobic processing solutions are used, for example, such hydrophilic regions may be set to be hydrophobic.

Instead of wafers, other substrates such as an FPD (flat panel display), a masking reticle for photomasking or the like may also be used in embodiments of the present invention.

A template according to an embodiment of the present invention is used for supplying a processing solution to predetermined positions of a substrate. Such a template has the following: multiple opening portions formed in positions on its front surface corresponding to the predetermined positions; flow channels penetrating from the opening portions to a back surface in a thickness direction for flowing a processing solution; first hydrophilic regions set to be hydrophilic on the front surface surrounding the opening portions; and second hydrophilic regions set to be hydrophilic on the inner surfaces of the flow channels. The first hydrophilic regions are formed in positions that correspond to hydrophilic patterns set to be hydrophilic around the predetermined positions on a front surface of the substrate. The first hydrophilic regions are regions that surround the opening portions and are set to be hydrophilic relative to the other regions on the front surface of the template. Therefore, when forming first hydrophilic regions, it is an option to process the front surface of the template surrounding opening portions to be hydrophilic, or to process the other regions of the front surface of the template to be hydrophobic, or to conduct both hydrophilic and hydrophobic treatments. The second hydrophilic regions are regions set to be hydrophilic, the same as with the first hydrophilic regions. Also, hydrophilic patterns are portions that surround predetermined positions and are set to be hydrophilic relative to other regions on a substrate surface.

When supplying a processing solution to predetermined positions of a substrate using a template according to an aspect of the present invention, first, a front surface of a template and a front surface of a substrate overlap in a way that positions of the first hydrophilic regions correspond to positions of the hydrophilic patterns. Then, a processing solution is supplied to flow channels of the template to flow through the flow channels. The processing solution infiltrates and fills between the first hydrophilic regions and the hydrophilic patterns through capillary action. Then, the template rises relative to the substrate due to surface tension or the like of the filled processing solution. At that time, the processing solution is further supplied to the flow channels so that the processing solution is supplied through opening portions to predetermined positions of the substrate. During that time, because of the above surface tension of the processing solution filled between the first hydrophilic regions and the hydrophilic patterns, restoration force is exerted on the template to cause its movement. Accordingly, even when positions of opening portions of the template and the predetermined positions of the substrate are shifted from each other, template moves due to the above-described restoration force so that positions of the template and the substrate are adjusted highly accurately. Thus, the processing solution is properly supplied from the opening portions to the predetermined positions of the substrate. Moreover, opening portions of the template themselves are formed with high positional accuracy by mechanical processing, or by conducting photolithographic and etching processes together, for example. Therefore, using a template of the present embodiment, a processing solution is supplied with high positional accuracy to predetermined positions of a substrate. Also, since a processing solution is supplied to a substrate with high positional accuracy, the substrate is processed properly.

Another aspect of the present invention is a method for processing a substrate by supplying a processing solution to predetermined positions of the substrate. A template used in such a method has multiple opening portions formed in positions on its front surface that correspond to the predetermined positions, flow channels penetrating from the opening portions to a back surface in a thickness direction for flowing a processing solution, first hydrophilic regions set to be hydrophilic around the opening portions on the front surface, and second hydrophilic regions set to be hydrophilic on the inner surfaces of the flow channels. A substrate has hydrophilic patterns set to be hydrophilic around the predetermined positions on a front surface. In a placement step, the front surface of the template and the front surface of the substrate overlap in a way that positions of the first hydrophilic regions correspond to positions of the hydrophilic patterns, and then in a solution filling step, a processing solution is supplied to the flow channels so that the processing solution is filled between the first hydrophilic regions and the hydrophilic patterns. Then, in a processing step, the processing solution, which is supplied to the flow channels, is supplied to the predetermined positions of the substrate, while positions of the template and the substrate are adjusted so that the opening portions align with the predetermined positions, and the predetermined positions of the substrate are processed.

According to embodiments of the present invention, a processing solution is supplied to predetermined positions of a substrate with high positional accuracy, allowing the substrate to be processed properly.

Obviously, numerous modifications and variations of the present invention are possible in light of the above teachings. It is therefore to be understood that within the scope of the appended claims, the invention may be practiced otherwise than as specifically described herein.

1-16. (canceled)

17. A template device for supplying a processing solution to a substrate, comprising:
a body having a front surface and a back surface, the front surface having a plurality of opening portions, the body having a plurality of flow channels extending from the opening portions to the back surface,
wherein the body has a plurality of first hydrophilic regions formed on the front surface such that each of the first hydrophilic regions surrounds each of the opening portions on the front surface, the body has a plurality of second hydrophilic regions formed such that each of the second hydrophilic regions forms at least a portion of an inner surface of each of the flow channels, the plurality of flow channels is configured to flow a processing solution through the body, and the plurality of first hydrophilic regions is positioned on the front surface of the body such that the plurality of first hydrophilic regions corresponds to a plurality of hydrophilic patterns formed on a surface of a substrate.

18. The template device according to claim 17, wherein the body has a plurality of back opening portions connected to the flow channels on the back surface and a plurality of third hydrophilic regions formed on the back surface of the body such that each of the third hydrophilic regions surrounds each of the back opening portions.

19. The template device according to claim 17, wherein the second hydrophilic regions of the body are formed from the opening portions of the body such that each of the second hydrophilic regions extends over the portion of the inner surface of each of the flow channels.

20. The template device according to claim 17, further comprising a driving mechanism configured to oscillate the body in a state where the body is attached and overlapping with the substrate.

21. The template device according to claim 17, wherein the plurality of flow channels is configured to flow the processing solution selected from the group consisting of an etching solution, a plating solution, an insulative film forming solution, a cleaning solution and pure water.

22. The template device according to claim 17, wherein the plurality of opening portions on the front surface is positioned to correspond to a plurality of positions for forming a plurality of penetrating electrodes in the substrate.

23. The template device according to claim 22, wherein the body has a plurality of second opening portions formed on the front surface and a plurality of second flow channels extending through the body from the plurality of second opening portions, respectively, and the plurality of second opening portions is formed on the front surface of the body such that the plurality of second opening portions is positioned to correspond to a plurality of scribe lines to be formed on the substrate for forming a plurality of semiconductor chips.

24. The template device according to claim 17, wherein the body has a plurality of grooves formed on the front surface where the first hydrophilic regions are not formed such that the grooves are recessed with respect to the first hydrophilic regions.

25. A method for supplying a processing solution to a substrate, comprising:
providing a template device comprising a body having a front surface and a back surface, the front surface having a plurality of opening portions, the body having a plurality of flow channels extending from the opening portions to the back surface, the body having a plurality of first hydrophilic regions formed on the front surface such that each of the first hydrophilic regions surrounds each of the opening portions on the front surface, the body having a plurality of second hydrophilic regions formed such that each of the second hydrophilic regions forms at least a portion of an inner surface of each of the flow channels, the plurality of flow channels being configured to flow a processing solution through the body, and the plurality of first hydrophilic regions being positioned on the front surface of the body such that the plurality of first hydrophilic regions corresponds to a plurality of hydrophilic patterns formed on a surface of a substrate;
placing the front surface of the body to a surface of the substrate such that the first hydrophilic regions of the template device correspond to the hydrophilic patterns on the substrate and form spaces between the first hydrophilic regions and the hydrophilic patterns on the substrate, respectively;
supplying a processing solution to the flow channels such that the processing solution fills the spaces formed between the first hydrophilic regions of the template device and the hydrophilic patterns on the substrate;
aligning the opening portions of the template device and a plurality of predetermined positions on the substrate such that the processing solution supplied to the flow channels is supplied to a plurality of portions of the substrate at the predetermined positions; and
processing the portions of the substrate at the predetermined positions with the processing solution.

26. The method according to claim 25, wherein the supplying of the processing solution includes filling the processing solution in the flow channels before the placing of the template device.

27. The method according to claim 25, further comprising removing an excess portion of the processing solution remaining on the back surface of the template device after the processing, wherein the supplying of the processing solution includes supplying the processing solution into the flow channels from a back-surface side of the body.

28. The method according to claim 25, wherein the second hydrophilic regions of the body are formed from the opening portions of the body such that each of the second hydrophilic regions extends over the portion of the inner surface of each of the flow channels.

29. The method according to claim 25, further comprising oscillating the template device in at least one of the supplying of the processing solution and the processing of the substrate.

30. The method according to claim 25, wherein the processing solution is selected from the group consisting of an etching solution, a plating solution, an insulative film forming solution, a cleaning solution and pure water.

31. The method according to claim 25, wherein the processing of the substrate includes forming in the substrate a plurality of holes for a plurality of penetrating electrodes at the predetermined positions.

32. The method according to claim 31, wherein the body has a plurality of grooves formed on the front surface where the first hydrophilic regions are not formed such that the grooves are recessed with respect to the first hydrophilic regions, and the processing of the substrate includes forming a plurality of scribe lines for forming a plurality of semiconductor chips.
